(19) United States
(12) Patent Application Publication
(10) Pub. No.: US 2025/0159879 A1
(43) Pub. Date: May 15, 2025

(54) NON-VOLATILE MEMORY DEVICE FOR LOW OPERATION VOLTAGE

(71) Applicant: eMemory Technology Inc., HSINCHU (TW)

(72) Inventors: Wein-Town SUN, Zhubei City (TW); Hsueh-Wei CHEN, Zhubei City (TW)

(73) Assignee: eMemory Technology Inc., HSINCHU (TW)

(21) Appl. No.: 18/788,920

(22) Filed: Jul. 30, 2024

Related U.S. Application Data
(60) Provisional application No. 63/598,558, filed on Nov. 14, 2023.

(51) Int. Cl. H10B 41/35; H01L 29/423; H01L 29/788

(52) U.S. Cl. CPC H10B 41/35; H10D 30/685; H10D 30/6892

(57) ABSTRACT

A non-volatile memory device including a substrate and a memory cell. The memory cell includes a select transistor, a floating gate transistor, and a metal conductor. The select transistor includes a select gate structure over the substrate, a first source/drain region on a first side of the select gate structure, and a second source/drain region on a second side of the select gate structure opposite the first side. The floating gate transistor includes a floating gate structure over the substrate, the second source/drain region on a third side of the floating gate structure, and a third source/drain region on a fourth side of the floating gate structure opposite the third side. The metal conductor is over and electrically isolated from the floating gate structure. The floating gate transistor further includes a first low-voltage lightly doped drain between the floating gate structure and the third source/drain region.

### CROSS REFERENCE TO RELATED APPLICATIONS

This application claims the benefit of U.S. Provisional Application No. 63/598,558, filed on Nov. 14, 2023, the entirety of which is/are incorporated by reference herein.

### BACKGROUND OF THE INVENTION

### Field of the Invention

The present invention relates to a non-volatile memory device, and, in particular, a non-volatile memory device with low area penalty and low power consumption.

### Description of the Related Art

The non-volatile memory devices have been developed. One type of the non-volatile memory devices is electrically erasable programmable read-only memory (EEPROM). The EEPROM can be applied in digital cameras, video game consoles, personal digital assistants, telephone recording devices, and programmable IC products. The method of programming/erasing the EEPROM is to drive in/out the electrons into/from the floating gate in the EEPROM.

However, although existing technologies for non-volatile memory devices have been generally adequate for their intended purposes, they have not been entirely satisfactory in all respects.

### BRIEF SUMMARY OF THE INVENTION

The present disclosure provides a non-volatile memory device including a substrate and a memory cell. The memory cell includes a select transistor, a floating gate transistor, and a metal conductor. The select transistor includes a select gate structure over the substrate, a first source/drain region on a first side of the select gate structure, and a second source/drain region on a second side of the select gate structure opposite the first side. The floating gate transistor includes a floating gate structure over the substrate, the second source/drain region on a third side of the floating gate structure, and a third source/drain region on a fourth side of the floating gate structure opposite the third side. The metal conductor is over and electrically isolated from the floating gate structure. The floating gate transistor further includes a first low-voltage lightly doped drain between the floating gate structure and the third source/drain region.

### BRIEF DESCRIPTION OF THE DRAWINGS

In order to describe the manner in which the above-recited and other advantages and features of the disclosure can be obtained, a more particular description of the principles briefly described above will be rendered by reference to specific examples thereof which are illustrated in the appended drawings. Understanding that these drawings depict only exemplary aspects of the disclosure and are not therefore to be considered to be limiting of its scope, the principles herein are described and explained with additional specificity and detail through the use of the accompanying drawings.

FIG. 1A illustrates a top view (or a layout) of a non-volatile memory device, in accordance with some embodiments of the present disclosure.

FIG. 1B illustrates a Y-Z cross-sectional view of the non-volatile memory device along a line A-A′ of FIG. 1A, in accordance with some embodiments of the present disclosure.

FIG. 2 illustrates a Y-Z cross-sectional view of the non-volatile memory device along the line A-A′ of FIG. 1A, in accordance with some alternative embodiments of the present disclosure.

FIG. 3 illustrates a Y-Z cross-sectional view of the non-volatile memory device along the line A-A′ of FIG. 1A, in accordance with some alternative embodiments of the present disclosure.

FIG. 4 illustrates a Y-Z cross-sectional view of the non-volatile memory device along the line A-A′ of FIG. 1A, in accordance with some alternative embodiments of the present disclosure.

### DETAILED DESCRIPTION OF THE INVENTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

For purposes of the present detailed description, unless specifically disclaimed, the singular includes the plural and vice versa; and the word “including” means “including without limitation.” Moreover, words of approximation, such as “about,” “almost,” “substantially,” “approximately,” and the like, can be used herein to mean “at, near, or nearly at,” or “within 3-5% of,” or “within acceptable manufacturing tolerances,” or any logical combination thereof, for example.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

The terminology used herein is for the purpose of describing particular embodiments only, and is not intended to be limiting of the invention. As used herein, the singular forms “a”, “an” and “the” are intended to include the plural forms as well, unless the context clearly indicates otherwise. Furthermore, to the extent that the terms “including,” “includes,” “having,” “has,” “with,” or variants thereof, are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art. Furthermore terms, such as those defined in commonly used dictionaries, should be interpreted as having a meaning that is consistent with their meaning in the context of the relevant art, and will not be interpreted in an idealized or overly formal sense unless expressly so defined herein.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated.

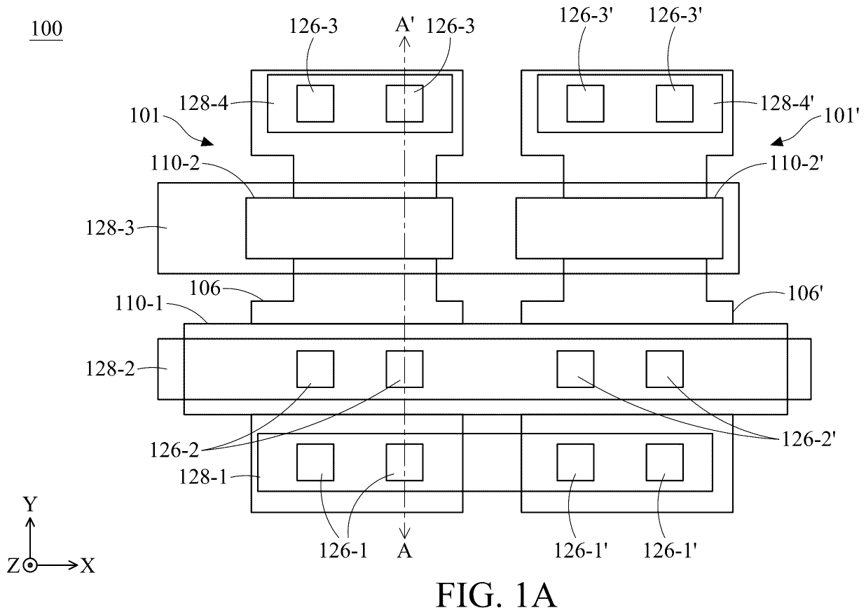

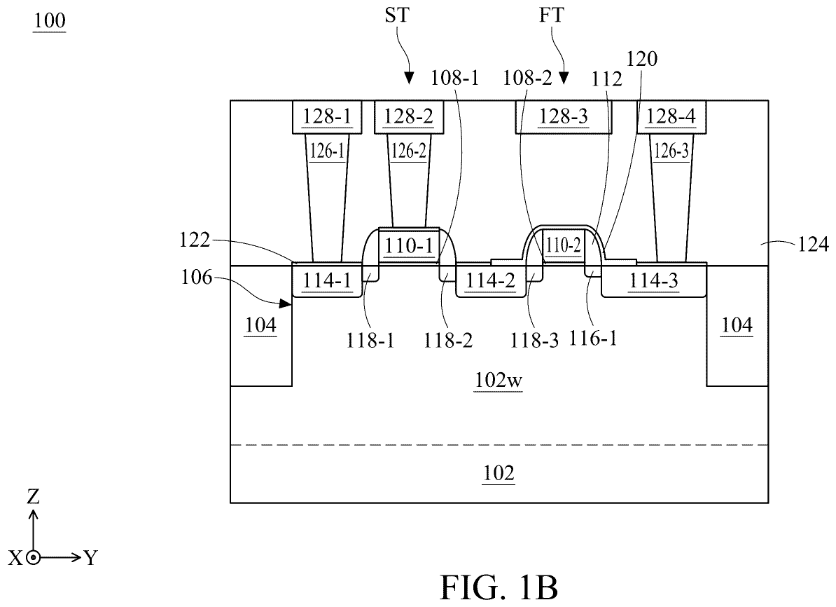

FIG. 1A illustrates a top view (or a layout) of a non-volatile memory device 100, in accordance with some embodiments of the present disclosure. FIG. 1B illustrates a Y-Z cross-sectional view of the non-volatile memory device 100 along a line A-A′ of FIG. 1A, in accordance with some embodiments of the present disclosure. As shown in FIG. 1A, the non-volatile memory device 100 includes two memory cells 101 and 101′ arranged in the X-direction. The memory cells 101 and 101′ have the same function and operation. The memory cells 101 and 101′ also have the same features and components. For the sake of distinction and simplicity, the reference numbers of the features/components in the memory cell 101′ similar or the same as that shown in memory cell 101 are additionally labeled with “′” and may not repeatedly described in detail. Although the non-volatile memory device 100 shown in FIG. 1A includes two memory cells 101 and 101′, it should be noted that the non-volatile memory device 100 may include more memory cells similar to the memory cells 101 and 101′ arranged in rows and columns into a memory array, in accordance with some embodiments.

The non-volatile memory device 100 includes a substrate 102, over/in which the various features are formed, such as gate structures and source/drain region, as shown in FIG. 1B. The substrate 102 may contains a semiconductor material, such as bulk silicon (Si). Alternatively, the substrate 102 may be a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates may be fabricated using separation by implantation of oxygen (SIMOX), wafer bonding, and/or other suitable methods.

In some embodiments, a p-type well 102w is formed in or on the substrate 102, as shown in FIG. 1B. In the present embodiment, the p-type well 102w is a p-type doped region configured for n-type transistors. The p-type well 102w is doped with p-type dopants, such as boron, indium, other p-type dopant, or a combination thereof. An ion implantation process, a diffusion process, and/or other suitable doping process can be performed to form the p-type well 102w. In other embodiments, a deep n-type well doped with n-type dopants (e.g., phosphorus, arsenic, other n-type dopant, or a combination thereof) is formed in the substrate 102, and the p-type well 102w is formed in the deep n-type well. Therefore, the various features of the memory cells 101 and 101′ discussed in below will be formed in/on the p-type well 102w.

The non-volatile memory device 100 further includes isolation structures 104 over/in the substrate 102 (the p-type well 102w), as shown in FIG. 1B. The isolation structures 104 may define active regions 106 and 106′ for the memory cells 101 and 101′, respectively, where the various features of the memory cells 101 and 101′ to be formed in/on. More specifically, the areas of the substrate 102 (the p-type well 102w) surrounded by the isolation structures 104 become the active regions 106 and 106′. The isolation structures 104 may include silicon oxide, silicon nitride, silicon oxynitride, other suitable isolation material (for example, including silicon, oxygen, nitrogen, carbon, or other suitable isolation constituent), or a combination thereof. The isolation structures 104 may include different structures, such as shallow trench isolation (STI) structures, deep trench isolation (DTI) structures, and/or local oxidation of silicon (LOCOS) structures. In some embodiments, STI features include a multi-layer structure that fills the trenches, such as a silicon nitride comprising layer disposed over a thermal oxide comprising liner layer. In yet another example, STI features include a bulk dielectric layer disposed over a liner dielectric layer, where the bulk dielectric layer and the liner dielectric layer include materials depending on design requirements.

The memory cell 101 further includes gate dielectric layers 108-1 and 108-2 (may be collectively referred to as gate dielectric layers 108) over the substrate 102, the p-type well 102w, and/or the active region 106. The memory cell 101 further includes gate electrode layers 110-1 and 110-2 (may be collectively referred to as gate electrode layers 110) over the gate dielectric layers 108-1 and 108-2, respectively, as shown in FIGS. 1A and 1B. As shown in FIG. 1A, the gate electrode layers 110-1 and 110-2 extend in the X-direction to across the active regions 106. Furthermore, the gate electrode layer 110-1 is shared by the memory cells 101 and 101′, as show in FIG. 1A. In some embodiments, the gate electrode layers 110-1 and 110-2 are arrange in the Y-direction. The gate electrode layers 110 and the gate dielectric layers 108 may be referred to as gate structures, in accordance with some embodiments.

In the present disclosure, the gate dielectric layer 108-1 and the gate electrode layer 110-1 are used for a select transistor ST. Therefore, the gate electrode layer 110-1 may be referred to as the select gate electrode layer and be referred to as the select gate or select gate structure together with the gate dielectric layer 108-1. Furthermore, the gate dielectric layer 108-2 and the gate electrode layer 110-2 are used for a floating gate transistor FT. Therefore, the gate electrode layer 110-2 may be referred to as the floating gate electrode layer and be referred to as the floating gate or floating gate structure together with the gate dielectric layer 108-2.

The gate dielectric layers 108 may be silicon oxide, silicon nitride, multilayers thereof, or the like, and may be deposited or thermally grown according to acceptable techniques. The formation methods of the gate dielectric layer may include molecular-beam deposition (MBD), atomic layer deposition (ALD), plasma-enhanced chemical vapor deposition (PECVD), chemical vapor deposition (CVD), or thermal oxidation, and the like. The gate electrode layers 110 may be formed of single crystal silicon or polycrystalline silicon, but may be formed by using other materials. In some embodiments, the material of the gate electrode layer may include a metal-containing material such as titanium nitride (TiN), tantalum nitride (TaN), tantalum carbide (TaC), cobalt (Co), ruthenium (Ru), aluminum (Al), combinations thereof, or multi-layers thereof.

In some embodiments, the memory cell 101 further includes gate spacers 112 on sidewalls of the gate dielectric layers 108 and the gate electrode layers 110 (i.e., the gate structures) and over the substrate 102 (the p-type well 102w), as shown in FIG. 1B. The gate spacers 112 may include multiple dielectric materials and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. In some embodiments, the gate spacers 112 may include a single layer or a multi-layer structure.

In some embodiments, the memory cell 101 further includes source/drain regions 114-1, 114-2, and 114-3 (may be collectively referred to as source/drain regions 114) on/in the substrate 102 (the p-type well 102w), as shown in FIG. 1B. Furthermore, as shown in FIG. 1B, the source/drain regions 114 are disposed on opposite sides of the respective gate dielectric layers 108 and the respective gate electrode layers 110 (i.e., the respective select gate structure and floating gate structure) in the Y-direction to form the select transistor ST and floating gate transistor FT. More specifically, the source/drain region 114-1 is disposed on one side of the gate electrode layer 110-1 in the Y-direction and the source/drain region 114-2 is disposed on opposite side of the gate electrode layer 110-1 in the Y-direction. Furthermore, the source/drain region 114-2 is also disposed on one side of the gate electrode layer 110-2 in the Y-direction and the source/drain region 114-3 is disposed on opposite side of the gate electrode layer 110-2 in the Y-direction. In some aspects, the source/drain region 114-2 is between the gate electrode layers 110-1 and 110-2 in the Y-direction. In other words, the source/drain region 114-2 is shared by the select transistor ST and the floating gate transistor FT. Furthermore, the source/drain region 114-1 is also between the isolation structure 104 and the gate electrode layer 110-1 (the gate dielectric layer 108-1) in the Y-direction, and the source/drain region 114-3 is also between another isolation structure 104 and the gate electrode layer 110-2 (the gate dielectric layer 108-2) in the Y-direction. The source/drain regions 114 may also be referred to as source/drain, or source/drain features. In some embodiments, a source/drain region may refer to a source or a drain, individually or collectively dependent upon the context. The source/drain regions 114 may be formed by using ion implantation. More specifically, portions of the substrate 102 (the p-type well 102w) are doped with dopants by ion implantation to form the source/drain regions 114. In some embodiments, the source/drain regions 114 may have n-type dopants (such as phosphorus, arsenic, other n-type dopant, or a combination thereof). In some embodiments, the source/drain regions 114 may be referred to as n-type source/drain regions.

The memory cell 101 further includes a low-voltage lightly doped drain (LVLDD) 116-1 and medium-voltage lightly doped drains (MVLDDs) 118-1, 118-2, and 118-3 (may be collectively referred to as medium-voltage lightly doped drains 118). The LVLDDs are usually used for core device and the MVLDDs are usually used for input/output (I/O) device. A core device can withstand a low voltage stress and needs a lower operation voltage (e.g., 1.2V). An I/O device can withstand a high voltage stress and needs a higher operation voltage (e.g., 6V). The LVLDD 116-1 and the MVLDDs 118 are disposed in the substrate 102 (the p-type well 102w) and under the gate spacers 112, as shown in FIG. 1B. In some embodiments, the LVLDD 116-1 and the MVLDDs 118 are disposed on opposite sides of the gate electrode layers 110 in the Y-direction. Furthermore, the LVLDD 116-1 and the MVLDDs 118 are disposed between the gate electrode layers 110 and the source/drain regions 114. More specifically, the LVLDD 116-1 is disposed between the gate electrode layer 110-2 (the floating gate structure) and the source/drain region 114-3, the MVLDD 118-1 is disposed between the gate electrode layer 110-1 (the select gate structure) and the source/drain region 114-1, the MVLDD 118-2 is disposed between the gate electrode layer 110-1 (the select gate structure) and the source/drain region 114-2, and the MVLDD 118-3 is disposed between the gate electrode layer 110-2 (the floating gate structure) and the source/drain region 114-2.

The LVLDD 116-1 and the MVLDDs 118 may be also formed by using ion implantation, similar to the source/drain regions 114 discussed above. In some embodiments, the LVLDD 116-1 and the MVLDDs 118 may also have n-type dopants discussed above. The dopant concentrations of the LVLDD 116-1 and the MVLDDs 118 are lower than the dopant concentration of the source/drain regions 114. Furthermore, the dopant concentrations of the MVLDDs 118 are lower than the dopant concentration of the LVLDD 116-1. In some embodiments, the depths of the MVLDDs 118 are greater than the depth of the LVLDD 116-1, as shown in FIG. 1B.

The memory cell 101 further includes a dielectric layer 120 over the gate electrode layer 110-2. More specifically, the dielectric layer 120 is disposed over the gate electrode layer 110-2 and the gate spacers 112 on the opposite sidewalls of the gate electrode layer 110-2, as shown in FIG. 1B. Furthermore, the dielectric layer 120 is over and partially cover the source/drain regions 114-2 and 114-3. The dielectric layer 120 fully covers and is in contact with a top surface of the gate electrode layer 110-2 for protect the gate electrode layer 110-2 and the data therein (e.g., electrons, if present). The dielectric layer 120 is formed by one or more dielectric materials selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), or a combination thereof. In some embodiments, the dielectric layer 120 may include a single layer or a multi-layer structure.

The memory cell 101 further includes silicide features 122 over and in contact with the source/drain regions 114 and the gate electrode layer 110-1. In some embodiments, the silicide features 122 partially cover the source/drain regions 114-2 and 114-3, as shown in FIG. 1B. Furthermore, the gate electrode layer 110-2 is in direct contact with the dielectric layer 120 without any silicide feature formed between them. The silicide features 122 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. The silicide features 122 are used for reducing contact resistance between vias 126 (will be discussed in below) and the source/drain regions 114.

The non-volatile memory device 100 further includes an inter-layer dielectric (ILD) layer 124, the vias 126 (including the vias 126-1, 126-2, and 126-3), and metal conductors 128 (including the metal conductors 128-1, 128-2, 128-3, and 128-4), as shown in FIGS. 1A and 1B. The ILD layer 124 is over the substrate 102 (the p-type well 102w), the isolation structures 104, the gate dielectric layers 108, the gate electrode layers 110, the gate spacers 112, the source/drain regions 114, the dielectric layer 120, and the silicide features 122.

The ILD layer 124 includes a dielectric material including, for example, silicon oxide, silicon nitride, silicon oxynitride, TEOS-formed oxide, PSG, BPSG, low-k dielectric material, other suitable dielectric material, or combinations thereof. Exemplary low-k dielectric materials include FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, other low-k dielectric material, or combinations thereof. In some embodiments, the ILD layer 124 is a dielectric layer that includes a low-k dielectric material (generally referred to as a low-k dielectric layer). In some embodiments, the ILD layer 124 may include a multilayer structure having multiple dielectric materials.

The vias 126 and the metal conductors 128 are disposed in the ILD layer. The metal conductors 128-1 to 128-4 are over respective gate electrode layer 110 and respective source/drain regions 114. More specifically, as shown in FIGS. 1A and 1B, the metal conductor 128-1 is over and overlaps the source/drain region 114-1, the metal conductor 128-2 is over and overlaps the gate electrode layer 110-1, the metal conductor 128-3 is over and overlaps the gate electrode layer 110-2, and the metal conductor 128-4 is over and overlaps the source/drain region 114-3. The vias 126-1 are over and electrically connected to the source/drain region 114-1, so as to electrically connect the source/drain region 114-1 to the metal conductor 128-1. The vias 126-2 are over and electrically connected to the gate electrode layer 110-1, so as to electrically connect the gate electrode layer 110-1 to the metal conductor 128-2. The vias 126-3 are over and electrically connected to the source/drain region 114-3, so as to electrically connect the source/drain region 114-3 to the metal conductor 128-4. It is noted that the metal conductor 128-3 is electrically isolated from the gate electrode layer 110-2. More specifically, the dielectric layer 120 and the ILD layer 124 are between the metal conductor 128-3 and the gate electrode layer 110-2 to electrically isolate the metal conductor 128-3 from the gate electrode layer 110-2. Therefore, the gate electrode layer 110-2 keeps floating in the operation of the memory cell. The materials of the vias 126 and the metal conductors 128 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

As shown in FIG. 1A, the metal conductors 128 extend in the X-direction and are arranged in the Y-direction. The metal conductors 128-2 and 128-3 are disposed overlapped with (or across) gate electrode layers 110-1, 110-2, and 110-2′ in the top view, as shown in FIG. 1A. In some embodiments, a width of the metal conductor 128-3 in the Y-direction is greater than a width of the metal conductor 128-2 in the Y-direction. Furthermore, the width of the metal conductor 128-3 in the Y-direction is greater than a length of the gate electrode layer 110-2 in the Y-direction. As shown in FIG. 1B, the metal conductors 128-1 to 128-4 are all in the same metal layer level in back-end-of-line (BEOL). Such metal level may be referred to as first metal layer (M1). Although one metal layer level is shown in FIG. 1B, it should be noted that there may be more vias and metal conductors at higher metal layer and electrically connected to the metal conductors 128 and the vias 126 to construct BEOL interconnection structure for the memory cell 101, in accordance with some embodiments.

In some embodiments, the metal conductors 128 are connected to power sources or voltage sources (not shown) to provide voltages (including the ground voltage) to the memory cell 101. In some embodiments, the metal conductor 128-1 serves as a source line (SL), the metal conductor 128-2 serves as a word line (WL), the metal conductor 128-3 serves as a control line (CL), and the metal conductor 128-4 serves as a bit line (BL).

When the memory cell 101 is programmed, the p-type well 102w is connected to ground, the metal conductor 128-1 (SL) is connected to ground, the metal conductor 128-2 (WL) is connected to a first positive voltage (may be referred to as voltage V₁ in below), the metal conductor 128-3 (CL) is connected to a second positive voltage (may be referred to as voltage V₂ in below), and the metal conductor 128-4 (BL) is connected to a third positive voltage (may be referred to as voltage V₃ in below). As such, the source/drain region 114-1 is connected to ground, the gate electrode layer 110-1 is connected to the voltage V₁, and the source/drain region 114-3 is connected to the voltage V₃. As discussed above, the gate electrode layer 110-2 is floating. In some embodiments, the voltage V₁ is in a range from about the voltage V₃/8 to about the voltage V₃. In some embodiments, the voltage V₂ is greater than or equal to (≥) about the voltage V₃. In some embodiments, the voltage V₃ is in a range from about 6 V to about 6.5 V.

With the above programming voltage condition, channel hot electron (CHE) injection is induced in the substrate 102 under the gate electrode layer 110-2 (the floating gate structure), and the channel hot electrons are injected into the gate electrode layer 110-2. The channel hot electrons are stored in the gate electrode layer 110-2. Therefore, the threshold voltage of the floating gate transistor FT is changed. Such programming method may be referred to as channel hot electrons programming (CHE PGM).

When the memory cell 101 is erased, the p-type well 102w is connected to ground, the metal conductor 128-1 (SL) is connected to ground, the metal conductor 128-2 (WL) is connected to ground, the metal conductor 128-3 (CL) is connected to a negative voltage (may be referred to as voltage V₄ in below), and the metal conductor 128-4 (BL) is connected to a positive voltage (may be referred to as voltage V₅ in below). As such, the source/drain region 114-1 is connected to ground, the gate electrode layer 110-1 is connected to ground, and the source/drain region 114-3 is connected to voltage V₅. As discussed above, the gate electrode layer 110-2 is floating. In some embodiments, the voltage V₅ is greater than the voltage V₄.

With the above erasing voltage condition, band-to-band hot hole (BBHH) injection is induced in the substrate 102 (p-type well 102w) under the gate electrode layer 110-2 (the floating gate structure), and the band-to-band hot holes are injected into the gate electrode layer 110-2. If the gate electrode layer 110-2 has electrons (the channel hot electrons from programming), the band-to-band hot holes combine with the electrons to remove the electrons stored in the gate electrode layer 110-2. Therefore, the threshold voltage of the floating gate transistor FT is changed into that before programming. Such erasing method may be referred to as band-to-band hot holes erasing (BBHH ERS).

As discussed above, the threshold voltage of the floating gate transistor FT will be changed depending on whether the electrons are stored in the gate electrode layer 110-2. Such threshold voltage changing can be known by reading the memory cell 101. When the memory cell 101 is read, the p-type well 102w is connected to ground, the metal conductor 128-1 (SL) is connected to ground, the metal conductor 128-2 (WL) is connected to a positive voltage (may be referred to as voltage V₆ in below), the metal conductor 128-3 (CL) is connected to a positive voltage (may be referred to as voltage Vin below), and the metal conductor 128-4 (BL) is connected to a positive voltage (may be referred to as voltage V₈ in below). In some embodiments, the voltage V₆ is greater than the threshold voltage of the select transistor ST. In some embodiments, the voltage V₇ is in a range from about 0 V to about the voltage V₆. In some embodiments, the voltage V₈ is equal to about the voltage V₆. Therefore, according to the read current, it can be known whether the memory cell 101 is programmed.

As discussed above, the memory cell 101 is erased by injecting the BBHH into the gate electrode layer 110-2 to remove the electrons storing in the gate electrode layer 110-2. Therefore, compared to conventional method, there is no need to extend the gate electrode layer 110-2 of the floating gate transistor FT into an additional area to drive out the electrons storing in the gate electrode layer 110-2. As shown in FIG. 1A, the gate electrode layer 110-2 is a straight line extending in the X-direction without any extension branches to other area. Therefore, compared to conventional memory cell, the memory cell 101 is smaller and has low area penalty.

Furthermore, due to the metal conductor 128-3 (CL) is connected to the voltage V₂ or the voltage V₄ discussed above, the metal conductor 128-3 (CL) facilitates the CHE or the BBHH to be injected into the gate electrode layer 110-2. As shown in FIGS. 1A and 1B, when viewing from Z-direction, the metal conductor 128-3 fully covers and overlaps the gate electrode layer 110-2 for facilitates the injection of the carriers (CHE and BBHH). In Y-direction, the width of the metal conductor 128-3 is greater than or equal to the width of the gate electrode layer 110-2. Therefore, when viewing from Z-direction, the metal conductor 128-3 may fully cover and overlap the MVLDD 118-3, the LVLDD 116-1 and the gate spacers 112, as shown in FIG. 1B. In other words, projections vertically projected by the gate electrode layers 110-2 and 110-2′ along the Z-direction onto an imaginary plane locate within a projection vertically projected by the metal conductor 128-3 along the Z-direction onto such imaginary plane.

As discussed above, the memory cell 101 has the LVLDD 116-1 with lower depth and higher dopant concentration than general LDD (e.g., the MVLDD). The CHE and BBHH can be easier to be induced with such LVLDD 116-1 during programming and erasing in the memory cell 101 to facilitate programming and erasing. Therefore, the memory cell 101 may also have smaller operation voltages for programming, erasing, and reading compared to conventional memory cell. Therefore, the power consumption of the memory cell 101 is improved.

The gate electrode layer 110-2 can be designed with smaller length in the Y-direction with such metal conductor 128-3 (CL) and LVLDD 116-1. In some embodiments, the length of the gate electrode layer 110-2 in the Y-direction is less than the length of the gate electrode layer 110-1 in the Y-direction, as shown in FIGS. 1A and 1B. Therefore, the memory cell 101 has benefit of a small area.

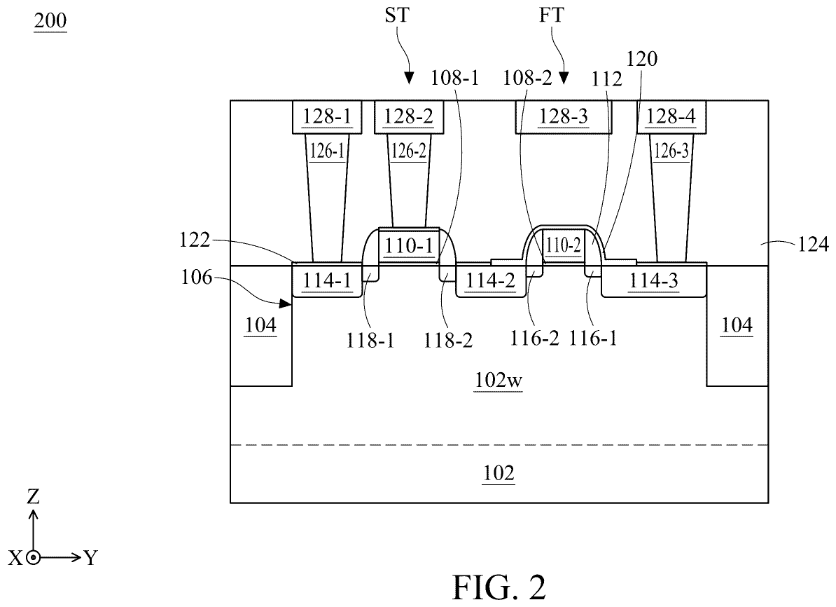

FIGS. 2 to 4 illustrate Y-Z cross-sectional views of the non-volatile memory devices 200, 300, and 400 along a line similar to the line A-A′ of FIG. 1A, in accordance with some alternative embodiments of the present disclosure. The non-volatile memory devices 200 shown in FIG. 2 is similar to the non-volatile memory device 100 shown in FIG. 1, except that the memory cell 101 of the non-volatile memory devices 200 has one more LVLDD. As shown in FIG. 2, the memory cell 101 includes LVLDD 116-2 replacing the MVLDD 118-3 shown in the memory cell 101 in FIG. 1B. In some embodiments, the LVLDD 116-2 is disposed between the gate electrode layer 110-2 (the floating gate structure) and the source/drain region 114-2.

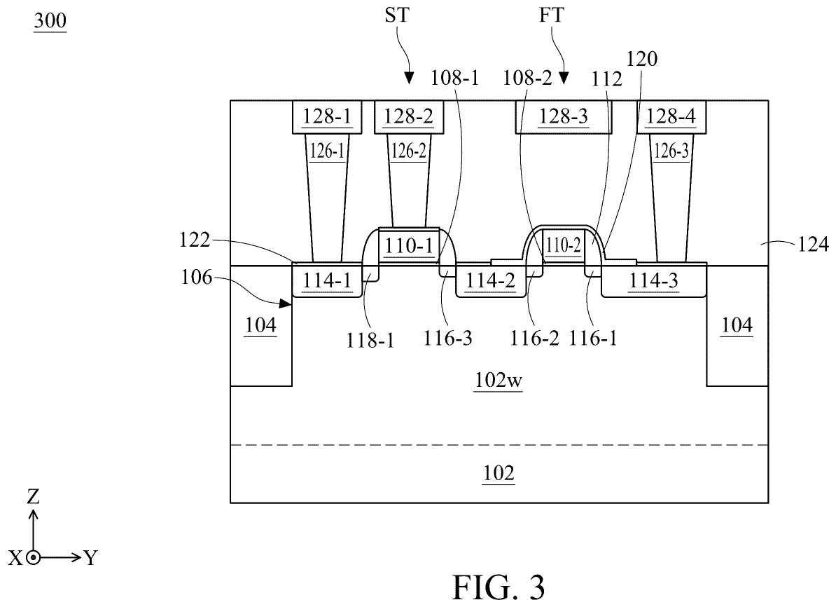

The non-volatile memory devices 300 shown in FIG. 3 is similar to the non-volatile memory device 200 shown in FIG. 2, except that the memory cell 101 of the non-volatile memory devices 300 has one more LVLDD. As shown in FIG. 3, the memory cell 101 includes LVLDD 116-3 replacing the MVLDD 118-2 shown in the memory cell 101 in FIG. 2. In some embodiments, the LVLDD 116-3 is disposed between the gate electrode layer 110-1 (the select gate structure) and the source/drain region 114-2.

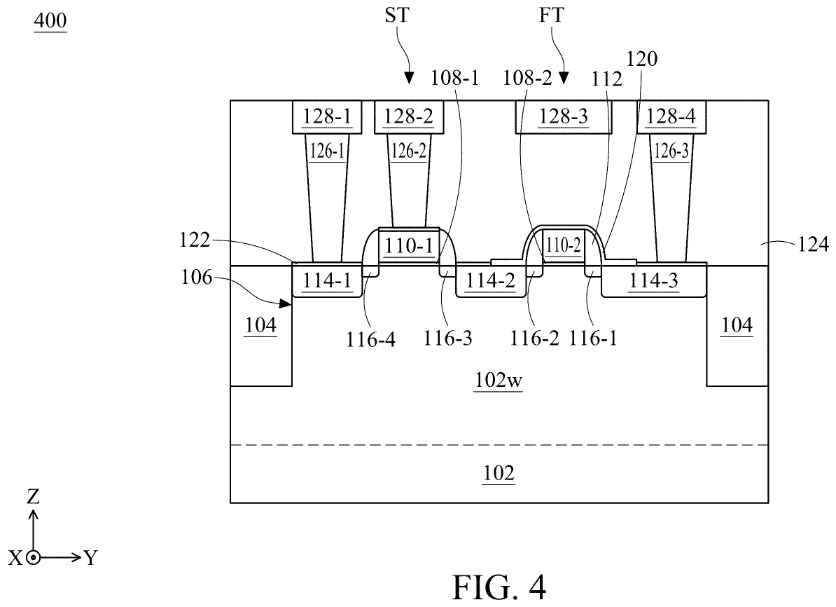

The non-volatile memory devices 400 shown in FIG. 4 is similar to the non-volatile memory device 300 shown in FIG. 3, except that the memory cell 101 of the non-volatile memory devices 400 has one more LVLDD. As shown in FIG. 4, the memory cell 101 includes LVLDD 116-4 replacing the MVLDD 118-1 shown in the memory cell 101 in FIG. 3. In some embodiments, the LVLDD 116-4 is disposed between the gate electrode layer 110-1 (the select gate structure) and the source/drain region 114-1.

The LVLDD 116-2 to 116-4 shown in FIGS. 2 to 4 are similar to the LVLDD 116-1 shown in FIG. 1B. As such, the LVLDD 116-2 to 116-4 also have lower depth and higher dopant concentration than general LDD (the MVLDD). The CHE can be easier to be induced with more LVLDD during programming in the memory cell 101 to facilitate programming, as discussed above. With more LVLDD, the gate electrode layers may be designed with smaller length in the Y-direction. In other words, the length of the gate electrode layer 110-2 in the Y-direction shown in FIGS. 2 to 4 are less than the length of the gate electrode layer 110-2 in the Y-direction shown in FIG. 1. The length of the gate electrode layer 110-1 in the Y-direction shown in FIG. 3 is less than the length of the gate electrode layers 110-1 in the Y-direction shown in FIGS. 1 and 2. The length of the gate electrode layer 110-1 in the Y-direction shown in FIG. 4 is less than the length of the gate electrode layer 110-1 in the Y-direction shown in FIG. 3. Therefore, the cell pitch of the memory cell 101 in the Y-direction shown in FIG. 1 is greater than the cell pitch of the memory cell 101 in the Y-direction shown in FIG. 2, the cell pitch of the memory cell 101 in the Y-direction shown in FIG. 2 is greater than the cell pitch of the memory cell 101 in the Y-direction shown in FIG. 3, and the cell pitch of the memory cell 101 in the Y-direction shown in FIG. 3 is greater than the cell pitch of the memory cell 101 in the Y-direction shown in FIG. 4.

The embodiments of the present disclosure offer advantages over existing art, though it should be understood that other embodiments may offer different advantages, not all advantages are necessarily discussed herein, and that no particular advantage is required for all embodiments. For example, embodiments discussed herein include a non-volatile memory device with a memory cell. The memory cell is programmed by channel hot electron mechanism and is erased by band-to-band hot hole mechanism, such that there is no need to extend the gate electrode layer of the floating gate transistor into an additional area to drive out the electrons stored in the gate electrode layer, thereby resulting the memory cell with low footprint/area penalty. Furthermore, the memory cell includes a metal conductor serving as control line over the gate electrode layer of the floating gate transistor and over the corresponding MVLDD and LVLDD(s). Therefore, the gate electrode layer of the floating gate transistor can be designed with small length and the power consumption of the memory cell is improved.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A non-volatile memory device, comprising:
a substrate; and
a memory cell, comprising:
a select transistor, comprising a select gate structure over the substrate, a first source/drain region on a first side of the select gate structure, and a second source/drain region on a second side of the select gate structure opposite the first side;
a floating gate transistor, comprising a floating gate structure over the substrate, the second source/drain region on a third side of the floating gate structure, and a third source/drain region on a fourth side of the floating gate structure opposite the third side; and
a metal conductor over and electrically isolated from the floating gate structure, wherein the floating gate transistor further comprises a first low-voltage lightly doped drain between the floating gate structure and the third source/drain region.

2. The non-volatile memory device as claimed in claim 1, wherein the floating gate transistor further comprises:
a first medium-voltage lightly doped drain between the floating gate structure and the second source/drain region,
wherein the select transistor further comprises:
a second medium-voltage lightly doped drain between the select gate structure and the second source/drain region; and
a third medium-voltage lightly doped drain between the select gate structure and the first source/drain region,
wherein dopant concentrations of the first, second, and third medium-voltage lightly doped drains are lower than a dopant concentration of the first low-voltage lightly doped drain.

3. The non-volatile memory device as claimed in claim 2, wherein depths of the first, second, and third medium-voltage lightly doped drains are greater than a depth of the first low-voltage lightly doped drain.

4. The non-volatile memory device as claimed in claim 1, wherein the floating gate transistor further comprises:
a second low-voltage lightly doped drain between the floating gate structure and the second source/drain region,
wherein the select transistor further comprises:
a first medium-voltage lightly doped drain between the select gate structure and the second source/drain region; and
a second medium-voltage lightly doped drain between the select gate structure and the first source/drain region,
wherein dopant concentrations of the first and second medium-voltage lightly doped drains are lower than dopant concentrations of the first and second low-voltage lightly doped drains.

5. The non-volatile memory device as claimed in claim 4, wherein depths of the first and second medium-voltage lightly doped drains are greater than depths of the first and second low-voltage lightly doped drains.

6. The non-volatile memory device as claimed in claim 1, wherein the floating gate transistor further comprises:
a second low-voltage lightly doped drain between the floating gate structure and the second source/drain region,
wherein the select transistor further comprises:
a third low-voltage lightly doped drain between the select gate structure and the second source/drain region; and
a medium-voltage lightly doped drain between the select gate structure and the first source/drain region,
wherein a dopant concentration of the medium-voltage lightly doped drain is lower than dopant concentrations of the first, second, and third low-voltage lightly doped drains.

7. The non-volatile memory device as claimed in claim 6, wherein a depth of the medium-voltage lightly doped drain is greater than depths of the first, second, and third low-voltage lightly doped drains.

8. The non-volatile memory device as claimed in claim 1, wherein the floating gate transistor further comprises:
a second low-voltage lightly doped drain between the floating gate structure and the second source/drain region,
wherein the select transistor further comprises:
a third low-voltage lightly doped drain between the select gate structure and the second source/drain region; and
a fourth low-voltage lightly doped drain between the select gate structure and the first source/drain region.

9. The non-volatile memory device as claimed in claim 1, further comprising:
a dielectric layer fully covering and in contact with a top surface of the floating gate structure.

10. The non-volatile memory device as claimed in claim 1, wherein a length of the floating gate structure in a Y-direction is less than a length of the select gate structure in the Y-direction.

11. The non-volatile memory device as claimed in claim 1, wherein the substrate has a p-type well, wherein the first, second, and third source/drain regions have n-type dopants and are disposed in the p-type well.

12. The non-volatile memory device as claimed in claim 11, wherein the substrate further comprises a deep n-type well, wherein the p-type well is formed in the deep n-type well.

13. The non-volatile memory device as claimed in claim 1, wherein when the memory cell is programmed, the p-type well is connected to ground, the select gate structure is connected to a first positive voltage, the floating gate structure is floating, the first source/drain region is connected to ground, the metal conductor is connected to a second positive voltage, and the third source/drain region is connected to a third positive voltage, wherein the second positive voltage is greater than or equal to the third positive voltage.

14. The non-volatile memory device as claimed in claim 1, wherein when the memory cell is erased, the p-type well is connected to ground, the select gate structure is connected to ground, the floating gate structure is floating, the first source/drain region is connected to ground, the metal conductor is connected to a negative voltage, and the third source/drain region is connected to a positive voltage.

15. The non-volatile memory device as claimed in claim 1, wherein the metal conductor fully covers and overlaps the floating gate structure.

16. The non-volatile memory device as claimed in claim 1, wherein the memory cell is programmed by inducing channel hot electron injection under the floating gate structure.

17. The non-volatile memory device as claimed in claim 1, wherein the memory cell is erased by inducing band-to-band hot hole injection under the floating gate structure.
